(19) United States
(12) Patent Application Publication
(10) Pub. No.: US 2009/0211797 A1
(43) Pub. Date: Aug. 27, 2009

(54) SEMICONDUCTOR PACKAGE

(75) Inventor: Daigo CHABATA, Tokyo (JP)

Correspondence Address: VOLENTINE & WHITT PLLC, ONE FREEDOM SQUARE, 11951 FREEDOM DRIVE SUITE 1260, RESTON, VA, 20190, US

(73) Assignee: OKI SEMICONDUCTOR CO., LTD., Tokyo (JP)

(21) Appl. No.: 12/358,272

(22) Filed: Jan. 23, 2009

(30) Foreign Application Priority Data
Feb. 22, 2008 (JP) 2008-041384

(51) Int. Cl. H05K 1/11

(52) U.S. Cl. 174/261

(57) ABSTRACT

A semiconductor package includes an IC chip having a rectangular (or square) semiconductor substrate, and an integrated circuit formed on a main surface of the semiconductor substrate. The semiconductor package also includes a support substrate on which the IC chip is mounted. A power source line is disposed on the main surface of the semiconductor substrate along the edge of the semiconductor substrate in the shape of a rectangle to supply a power source voltage to the integrated circuit. A main relay pad is provided on the semiconductor substrate and connected to one corner of the power source line. A secondary relay pad is provided on the semiconductor substrate and connected to another corner of the power source line. The semiconductor package also includes a support part to support the IC chip, an external power source supply terminal, and a relay line to connect both the main relay pad and the secondary relay pad to the external power source supply terminal.

### BACKGROUND OF THE INVENTION

1. Field of the Invention

The present invention relates to a semiconductor package including an integrated circuit (IC) chip and a support substrate to support the IC chip.

2. Description of the Related Art

In a technical field of semiconductor integrated circuits, layout modifications and improvements have been made along with the miniaturization of devices to reduce the size of the semiconductor integrated circuits and the manufacturing costs of the semiconductor integrated circuits. Japanese Patent Application Kokai (Laid-Open) No. 2000-58765 discloses a power source line that is arranged below the bonding pad to reduce the area of an IC chip. This power source line arrangement can reduce the IC chip area if compared with a power source line that extends on the IC chip surface in a way to avoid a bonding pad on the IC chip surface.

In a packaging process, the IC chip is mounted on a lead frame (i.e., the support substrate), and a bonding pad disposed at the surface of the IC chip is connected to a post part on the lead frame by wire bonding. As a result, it is possible to supply an external power source voltage to an integrated circuit formed in the IC chip through an external lead terminal of the semiconductor package, and it is also possible to extract (output) a signal generated by the integrated circuit. When the integrated circuit is operated by the external power source voltage supplied thereto, charge and discharge repeatedly occur in respective elements and devices of the integrated circuit. The voltage on the power source line formed in the IC chip is fluctuated statically or transiently by such charge and discharge. When the power source voltage fluctuates on the power source line, a circuit block connected to the power source line may operate in an unstable manner and/or may malfunction. For this reason, it is necessary to decide circuit design or pattern design in consideration of such voltage fluctuation; however, it is not easy to consider transient voltage fluctuation in a large-scale circuit. Consequently, a condenser is often interposed between a power source and a ground on a printed substrate having a semiconductor package mounted thereon to stabilize the power source voltage.

### SUMMARY OF THE INVENTION

Referring to FIG. 1 of the accompanying drawings, a power source supply path will be explained. The power source supply path extends from an integrated circuit formed in an IC chip to an external power source to receive a power source voltage from the external power source. Reference numeral 1 indicates an IC chip, reference numeral 2 indicates a support substrate on which the IC chip is mounted, and reference numeral 3 indicates a printed substrate on which the support substrate 2 is mounted. An external power source 108 is connected to a power source terminal of the printed substrate 3. A condenser 109 is connected between the power source terminal and a ground. An electric potential of the power source supply path is stabilized by the condenser 109. The power source voltage from the external power source 108 is supplied to the IC chip 1 via an on-substrate line 107 of the printed substrate 3, an external power source supply terminal 106 disposed on the support substrate, a relay line 105, a bonding post part 104, a bonding wire 103, and a power source pad 102 formed at the surface of the IC chip 1. The power source voltage supplied to the IC chip 1 is sent to respective circuit blocks in the integrated circuit through a power source line 101 connected to the power source pad 102. The power source line 101 serves to supply the power source voltage to the respective circuit blocks arranged in the IC chip 1. The power source line 101 is disposed, for example, to surround the circuit blocks. The power source line 101 has line resistance corresponding to the line length and line width thereof, and therefore, it is possible to illustrate the power source line 101 in the form of an equivalent circuit as shown in FIG. 1. This equivalent circuit has a plurality of resistors connected in the lattice form, as shown in FIG. 1. The IC chip has a plurality of circuit blocks.

When the circuit scale of the integrated circuit is relatively small, the power source voltage supplied to the power source line 101 through the above-described path may be stabilized by the provision of the condenser 109. However, when the circuit scale of the integrated circuit is greatly decreased and/or the line width is greatly increased, it is necessary to increase the line length of the power source line 101 and to decrease the line width of the power source line 101, which leads to the increase of line resistance and current density. As a result, it is possible to maintain the stability of the power source voltage in a region 110 relatively adjacent to the power source pad 102, but it is difficult to maintain the stability of the power source voltage in a region 111 remote from the power source pad 102 due to the voltage drop. That is, when the circuit scale of the integrated circuit is greatly decreased and/or the line width is greatly increased, it is difficult to supply a stable power source voltage to all the circuit blocks arranged on the IC chip. As a result, the circuits may operate in an unstable manner or malfunction in that circuit block which is disposed at the region 111 where it is difficult to receive the stable power source voltage through the power source line 101. Also, the failure of the circuit operation due to the fluctuation (unstableness) of the power source voltage is often observed at a wafer inspection process carried out after the manufacture of the IC chip or at an actual equipment test carried out after the IC chip is mounted on the printed substrate. When such failure is found, it is necessary to greatly change the circuit design or pattern design of the IC chip. This significantly delays the development of products, and increases development costs. Furthermore, if excessive measures (e.g., providing many capacitors) to prevent the recurrence of such failure are adopted, the area of the chip may be greatly increased.

An object of the present invention to provide a semiconductor package that is capable of preventing the failure of a circuit operation due to the fluctuation of power source voltage generated in an integrated circuit.

According to one aspect of the present invention, there is provided a semiconductor package that includes an IC chip having a rectangular semiconductor substrate and an integrated circuit formed on a main surface of the semiconductor substrate. The semiconductor package also includes a support substrate to support the IC chip. The integrated circuit includes a power source line disposed on the main surface of the semiconductor substrate along the edge of the semiconductor substrate in the shape of a rectangle to supply a power source voltage to the integrated circuit. The integrated circuit also includes a main relay pad connected to one corner of the power source line, and one more secondary relay pads connected to other corners of the power source line. The support substrate has an external power source supply terminal and a relay line to connect both the main relay pad and the secondary relay pad(s) to the external power source supply terminal. The external power source supply terminal and the relay line are disposed on the support substrate. The main and secondary relay pad(s) may be connected to other than the corners of the power supply line as long as the provision of the rely pads does not disturb the remaining elements of the IC chip.

The semiconductor package of the present invention has a plurality of power source voltage supply paths to the power source line on in the IC chip. Thus, a failure of the circuit operation due to the fluctuation of power source voltage generated on the power source line is prevented.

According to a second aspect of the present invention, there is provided a design method for the semiconductor package.

The design method includes:

a pattern designing step of making a first pattern that decides the disposition of the integrated circuit, the power source line, and the main relay pad on the semiconductor substrate;

an additional relay pad providing step of making a second pattern that decides the disposition of a plurality of candidates of secondary relay pads on the semiconductor substrate and decides the connection of the plurality of candidates of secondary relay pads to the power source line;

an IC chip manufacturing step of providing and connecting the integrated circuit, the power source line, the main relay pad and the secondary relay pad candidates on the semiconductor substrate based on the first and second patterns, thereby manufacturing the IC chip;

a step of measuring electrical potentials of the respective secondary relay pad candidates during a test operation of the manufactured IC chip;

a selection step of selecting at least one secondary relay pad from the candidates based on the measurement results of the electrical potentials of the respective secondary relay pad candidates; and

a step of mounting the IC chip on the support substrate and connecting the main relay pad and the selected secondary relay pad(s) to the external power source supply terminal via the relay line including bonding wires.

The additional relay pad providing step may include disposing the secondary relay pads in empty regions on the IC chip where the integrated circuit, the power source line, and the main relay pad are absent.

The secondary relay pads may be provided in corners of the IC chip.

The secondary relay pads may be provided in empty regions other than the corners of the IC chip.

The selection step may include selecting the secondary replay pad of which the electrical potential is not within a predetermined range, among the secondary relay pad candidates.

The main and secondary relay pads may be provided at predetermined intervals.

These and other objects, aspects and advantages of the present invention will become apparent to those skilled in the art from the following detailed description and appended claims when read and understood in conjunction with the accompanying drawings.

### BRIEF DESCRIPTION OF THE DRAWINGS

FIG. 1 illustrates a power source supply path of a conventional semiconductor package;

FIG. 2 illustrates a power source supply path of a semiconductor package according to an embodiment of the present invention;

FIG. 3 is a flow chart illustrating a design sequence for making a semiconductor package according to an embodiment of the present invention;

FIG. 4A illustrates a pattern layout of an IC chip according to an embodiment of the present invention before a secondary power source pad is provided; and

FIG. 4B illustrates a pattern layout of the IC chip after the secondary power source pad is provided.

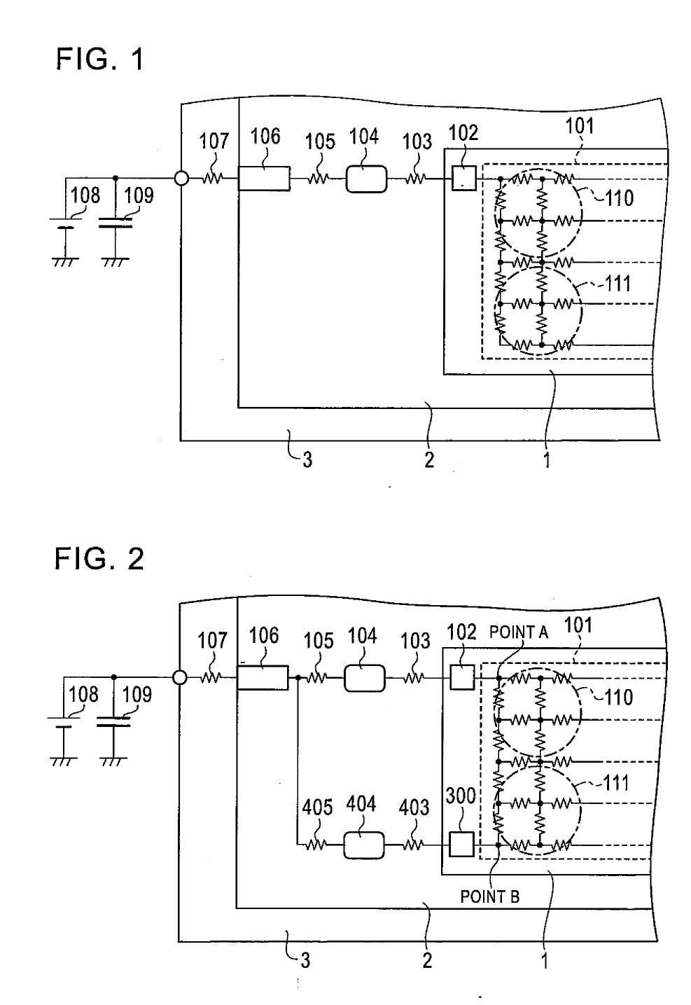

### DETAILED DESCRIPTION OF THE INVENTION

Now, preferred embodiments of the present invention will be described in detail with reference to the accompanying drawings. The same or similar elements are denoted by the same reference numerals even though they are depicted in different drawings.

Referring to FIG. 2, a power source supply path of a semiconductor package according to one embodiment of the present invention will be described. Reference numeral 1 designates an IC chip, reference numeral 2 designates a support substrate on which the IC chip is mounted, and reference numeral 3 designates a printed substrate on which the support substrate 2 is mounted.

The IC chip 1 has a rectangular or square semiconductor substrate. An integrated circuit including a plurality of circuit blocks is formed on the main (or upper) surface of the IC chip 1. Also, a power source line 101 is formed on the main surface of the IC chip 1 such that the power source line 101 is disposed along the edge of the IC chip 1 in the shape of a rectangle or square. That Is, the power source line 101 surrounds the integrated circuit. The respective circuit blocks constituting the integrated circuit are connected to the power source line 101. The circuit blocks are configured to receive power source voltage via the power source line 101. In a particular peripheral area of the IC chip 1 is formed a secondary power source pad (secondary relay pad) 300 in addition to a conventional power source pad (main relay pad) 102. The main power source pad 102 is connected, for example, to a corner (Point A in FIG. 2) of the rectangular power source line 101. The secondary power source pad 300 is connected, for example, to another corner (Point B in FIG. 2) of the power source line 101. It should be noted that a plurality of secondary power source pads 300 may be disposed on the IC chip 1 although only one pad 300 is illustrated in the drawing. If three secondary pads 300 are provided, these three secondary power source pads 300 are connected to three corners of the rectangular power source line 101 (excluding the corner A where the power source pad 102 is connected).

The IC chip 1 is fixed onto the support substrate 2, for example, by soldering. The primary power source pad 102 of the IC chip 1 is connected to a post part 104 formed on the support substrate 2 by a bonding wire 103. Also, the primary power source pad 102 of the IC chip 1 is connected to an external power source supply terminal 106 via a relay line 105 formed on the support substrate 2. On the other hand, the secondary power source pad 300 of the IC chip 1 is connected to a second post part 404 formed on the support substrate 2 by a bonding wire 403. Also, the secondary power source pad 300 of the IC chip 1 is connected to the external power source supply terminal 106 via a relay line 405 formed on the support substrate 2.

An external power source 108 is connected to a power source terminal of the printed substrate 3. A condenser 109 is connected in parallel to the external power source 108 to stabilize the voltage on the power source supply path. Alternatively, the condenser 109 may be disposed on the printed substrate 3 or in the support substrate 2. Power source voltage outputted from the external power source 108 is supplied to the external power source supply terminal 106 of the support substrate 2 via an on-substrate line 107 of the printed substrate 3.

Because the semiconductor package has the above-described structure, power source voltage is supplied to Point A on the power source line 101 via a power source supply path constituted by the power source pad 102, the bonding wire 103, the post part 104, the relay line 105, the external power source supply terminal 106, and the on-substrate line 107. Also, the power source voltage is supplied to Point B on the power source line 101 via another power source supply path constituted by the secondary power source pad 300, the bonding wire 403, the post part 404, the relay line 405, the external power source supply terminal 106, and the on-substrate line 107. In the semiconductor package according to the present invention, therefore, a plurality of power source supply paths are formed between the IC chip 1 and the external power source 108. Accordingly, it is possible to directly supply the power source voltage to a plurality of points on the power source line 101. The resistance of the bonding wire 403 and that of the in-package line 405 are very small as compared with the line resistance of the power source line 101. Consequently, an appropriate power source voltage is supplied to Point B on the power source line 101 via the newly formed power source supply path, thereby achieving the stabilization of an electrical potential at Point B and in the neighboring region 111. As a result, it is possible to prevent the malfunction of the respective circuit blocks which receive a power source voltage from the region 111 of the power source line 101. Also, when another secondary power source pad(s) 300 is (are) provided on the IC chip 1, a third power source voltage supply path (and a fourth power source voltage supply path) may extend from the external power source 108 to the IC chip 1. In this case, the respective secondary power source pads 300 (e.g., first, second and third secondary pads 300) are connected to respective corners of the power source line 101, and therefore, it is possible to effectively prevent the fluctuation of power source voltage on the power source line 101. It should be noted that the connection positions of the primary power source pad 102 and the secondary power source pad(s) 300 on the power source line 101 are not limited to the corners of the power source line 101. In any event, however, the primary power source pad 102 and the secondary power source pad(s) 300 are preferably connected to the power source line 101 at certain intervals, in consideration of power consumption at the respective circuit blocks.

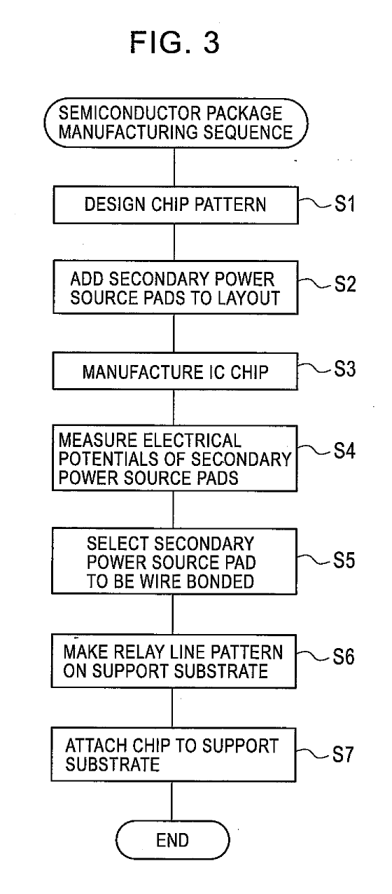

Hereinafter, an exemplary design sequence for the semiconductor package having the above-described structure will be described in detail. FIG. 3 is a flow chart illustrating a designing sequence for the semiconductor package. This flow chart shows a series of processes from the pattern designing for the IC chip 1 to the mounting of the IC chip 1 onto the support substrate 2.

First, pattern designing for an integrated circuit to be made on a semiconductor substrate is carried out (Step S1). At this Step S1, the layout (locations and arrangement) of circuit blocks, lines (wiring) and bonding pads on an IC chip substrate is decided considering the size (area) of the chip substrate, the heat generation of devices, and the stability of circuit operation. Also, at Step S1, the layout of a power source line 101 to supply a power source voltage to the respective circuit blocks is decided. The power source line 101 is disposed, for example, along the edge of the semiconductor substrate in the shape of a rectangle such that the power source line 101 surrounds all the circuit blocks. The power source line 101 supplies a power source voltage to the respective circuit blocks arranged across the surface of the IC chip substrate. The pattern design is roughly completed.

Subsequently (Step S2), an appropriate empty region is searched for in the IC chip pattern, and a position where a secondary power source pad 300 will be added is decided. That is, at Step S2, a region which is the most suitable for forming the secondary power source pad 300 is extracted (selected) from a plurality of candidates of empty regions on the chip substrate. The “empty region” is a region where the circuit blocks, the lines, and the bonding pads are not formed. The secondary power source pad 300 is disposed in the selected empty region, and designing of a pattern to connect the secondary power source pad 300 to the power source line 101 is carried out (Step S2). In the conventional art, only one power source pad is provided to supply a power source voltage into the IC chip, and only one connection point is provided between the power source pad and the power source line 101. That is, in the conventional IC chip, power source voltage is supplied to the power source line 101 via only one power source voltage supply path. According to the present invention, on the other hand, the empty region on the IC chip 1 is used to additionally provide the secondary power source pad 300. It should be noted that preferably a plurality of secondary power source pads 300 may be provided on the IC chip. How many pads 300 should be provided may depend upon the size and/or locations of the empty regions on the IC chip. Also, it is preferred to dispose the secondary power source pad(s) 300 adjacent to the power source line 101. For example, the secondary power source pad(s) 300 may be disposed at a corner(s) of the IC chip 1 since the empty region(s) is (are) easily created at the corner(s) of the IC chip 1 and the power source line 101 extends adjacent to the corners of the IC chip 1. In an exemplary embodiment, the secondary power source pads 300 are connected to corners of the rectangular power source line 101.

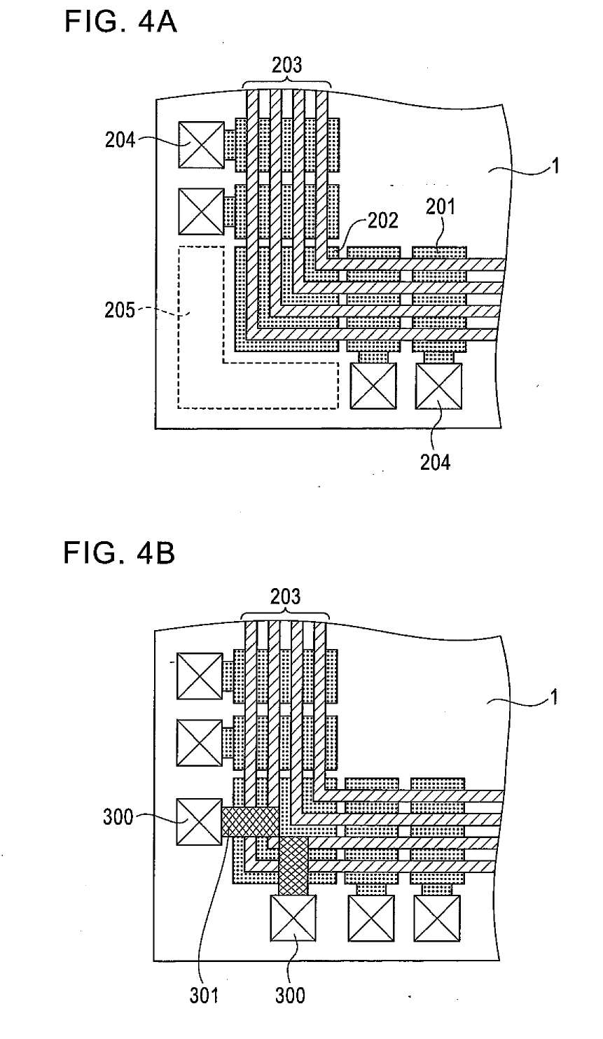

FIGS. 4A and 4B show the contents of Step S2 using an actual IC chip. FIG. 4A illustrates a layout of parts and wirings on an IC chip before the secondary power source pads 300 are provided, i.e., the IC chip after Step S1. FIG. 4B illustrates a layout of parts and wiring on the IC chip after the secondary power source pads 300 are provided. As shown in FIG. 4A, a plurality of input and output cells 201 and a plurality of bonding pads 204 associated with the input and output cells 201 are disposed in the IC chip 1. The respective bonding pads 204 are disposed, for example, at predetermined intervals along the edge of the chip. A corner cell 202 is also disposed on the IC chip 1. The power source line 203 (101) extends along the edge of the IC chip 1 in the shape of a rectangle such that the power source line 203 surrounds all the circuit blocks formed on the IC chip. The power source line 203 is disposed above the input and output cells 201 and the corner cell 202 to reduce the size of the IC chip. An insulation film is interposed between the power source line 203 and the input and output cells 201 and between power source line 203 and the corner cells 202. A power source pad (main relay pad) 102 (FIG. 2) is connected to one corner (not shown in FIG. 4A) of the power source line 203. External power source voltage is supplied to the power source line 203 via the power source pad 102. At another corner of the IC chip 1 is formed an empty region 205 where the circuit blocks, the bonding pads, and the lines are absent. At Step S2, a suitable empty region 205 on the chip is searched for, and a pair of secondary power source pads 300 are provided in the empty region 205 as depicted in FIG. 4B. The secondary power source pads 300 are connected to the power source line 203 via lines 301. When a similar empty region exists at another area on the IC chip, the secondary power source pad(s) 300 may also be provided in such empty region which is different from the empty region 205 shown in FIG. 4A. It should be noted that two secondary power source pads 300 are provided in the single empty area 205 in the illustrated embodiment, but only one secondary power source pad 300 may be provided in the single empty area 205. Two secondary power source pads 300 are provided in the empty area 205 in FIG. 4B, but one of them may be used for the wire boding. Providing a pair of pads 300 is practically advantageous because the directions of these two pads 300 are different and the wiring can be made to one of these two pads 300.

Subsequently, an IC chip is manufactured according to the patterns prepared by Steps S1 and S2 (Step S3).

It should be assumed here that the secondary pads 300 are provided at different corners of the IC chip.

Then, the manufactured IC chip is actually operated, using a known wafer measuring apparatus, to measure the electrical potentials of the respective secondary power source pads 300 at different corners of the IC chip (Step S4). That is, at Step S4, a plurality of secondary power source pads 300 connected to a plurality of points on the power source line 101 respectively are probed to measure their voltages, so as to observe the fluctuation of power source voltage on the power source line 101. Preferably, at this Step S4, the fluctuation of power source voltage on the power source line 101 is measured at high temperature and low temperature as well as room temperature. Use of such measurement results obtained under the different conditions contributes to complete prevention of the failure in an operation guarantee range. Furthermore, it is preferred to measure a power source voltage while intentionally fluctuating (shaking) the power source voltage.

Subsequently, at least one secondary power source pad 300 to which wire bonding should ultimately be made to establish a power source supply path, among the candidates of secondary power source pads 300 formed on the IC chip 1, is selected based on the electrical potentials of the respective secondary power source pads 300 measured at Step S4 (Step S5). At Step S4, the electrical potential on the power source line 101 is measured through each secondary power source pad 300. At Step S5, if the measured potential does not reach a predetermined electrical potential or when the electrical potential is not stable, it is considered that voltage drop has occurred at or in the vicinity of that part of the power source line 101 to which the secondary power source pad in question is connected. Therefore, the secondary power source pad where an appropriate electrical potential is not observed is selected as a target pad for wire bonding (i.e., wire bonding is performed to this selected secondary power source pad). That is, the selected secondary power source pad serves as a secondary relay pad of the present invention. On the other hand, when it is determined that the electrical potential on the power source line 101 measured through that secondary power source pad 300 at Step S4 is normal, wire bonding is not performed to that secondary power source pad. In this embodiment, it should be assumed that the left one pad 300 in a pad pair 300, 300 at the lower left corner of the IC chip is selected.

Subsequently, lines 105 and 405 (FIG. 2) are formed on the support substrate 2 considering the arrangement of the secondary power source pad 300 selected at Step S5 (Step S6). At this Step S6, a line pattern is prepared on the support substrate 2 such that the secondary power source pad (secondary relay pad) 300 selected at Step S5 and the power source pad (main relay pad) 102 are electrically connected to the external power source supply terminal 106.

Subsequently, the IC chip 1 manufactured at Step S3 is attached to the support substrate 2 prepared at Step S6 (Step S7). At this Step S7, first, a plurality of IC chips formed in a semiconductor wafer are diced to obtain individual IC chips. After that, each IC chip 1 is mounted on the support substrate 2, and the post parts on the support substrate are connected to the corresponding bonding pads formed on the surface of the IC chip by wire bonding. By this wire bonding process, the power source pad (main relay pad) 102 and the post part 104 are connected to each other via the bonding wire 103, and, at the same time, the secondary power source pad (secondary replay pad) 300 selected at Step S5 and the post part 404 are connected to each other via the bonding wire 403, as shown in FIG. 2. As a result, both the primary power source pad (main relay pad) 102 and the secondary power source pad (secondary replay pad) 300 are connected to the external power source supply terminal 106 via the bonding wires and the relay lines, respectively. After the completion of the wire bonding, the IC chip mounted on the support substrate 2 is encapsulated with resin by a well-known transfer molding method. The manufacturing of the semiconductor package according to the present invention is completed through the above-described process.

According the above-described design sequence, it is possible to obtain the following advantages. The candidates of second power source pads to introduce a power source voltage into the IC chip are already prepared at the time of the IC chip pattern designing, and therefore, it is not necessary to wholly readjust the pattern design of the IC chip, even if a failure due to the fluctuation of the power source voltage occurs in the chip. Thus, it is possible to solve the problem that the product development schedule is delayed to deal with the failure caused by power source voltage fluctuation. Also, the secondary power source pad(s) is (are) arranged using the empty region(s) on the IC chip after the layout of the circuit blocks and the lines is decided. Therefore, providing the second power source pad(s) does not increase the chip area (chip size). Also, at least one of the candidates of secondary power source pads, which are prepared in advance, is selected based on an actual circuit operation, and wire bonding is performed to the selected secondary power source pad(s). Therefore, it is possible to prevent the occurrence of a failure, and it is now unnecessary to take excessive measures such as providing an increased area for the power source line. Furthermore, the secondary power source pad for wire bonding is selected based on the actual measurement before performing the wiring boding process, and therefore, it is not necessary to perform wire bonding to all the candidates of the secondary power source pads. Thus, it is possible to restrain the increase of manufacturing costs and the decrease of productivity due to the increase of the number of times the wire bonding should be performed.

The disposition of the main power source pad and the secondary power source pad(s) at the corners of the IC chip is described as an example in the above-described embodiment; however, the secondary power source pad(s) may be disposed in another region(s) of the IC chip. Also, the single external power source is adopted in the above-described embodiment; however, it is possible to adopt a plurality of external power sources. Also, the formation of the power source supply path to the power source line is illustrated and described in the embodiment; however, such formation of the power source supply path is applicable to a ground line. This will be described in detail below. The ground line to supply ground electrical potentials to the respective circuit blocks may be disposed along the edge of the semiconductor substrate in the shape of a rectangle in the same manner as the power source line in the IC chip. When the circuit scale of the integrated circuit formed in the semiconductor substrate is increased, electric current flowing in the ground line increases, and, when the ground line resistance increases, voltage drop occurs on the ground line. As a result, appropriate ground electrical potentials may not be supplied to the respective circuit blocks, and therefore, the malfunction may be caused. This problem may be solved by the same methodology as taught by the above-described embodiment. Specifically, additional ground pads (secondary ground pads) may be provided to supply a ground electrical potential into the IC chip at Step S2 of the flow chart shown in FIG. 3. The secondary ground pads are connected to the ground line. At Step S4, the electrical potentials of the respective secondary ground pads are measured during the actual circuit operation. At Step S5, the secondary ground pad where an appropriate electrical potential is not observed is selected based on the measurement results at Step S4, and wire bonding is performed to the selected secondary ground pad. At Step S7, the selected secondary ground pad and the corresponding post part on the support substrate are connected to each other, and the secondary ground pad is connected to a ground terminal of the support substrate. Consequently, a new ground electrical potential supply path is provided. Thus, the electrical potential of the ground line becomes stable, and the malfunction of the respective circuit blocks is prevented.

This application is based on Japanese Patent Application No. 2008-41384 filed on Feb. 22, 2008 and the entire disclosure thereof is incorporated herein by reference.

What is claimed is:

1. A semiconductor package comprising:
an IC chip including a rectangular or square semiconductor substrate and an integrated circuit formed on a main surface of the semiconductor substrate; and
a support substrate to support the IC chip,
wherein the integrated circuit includes a power source line disposed on the main surface of the semiconductor substrate along the edge of the semiconductor substrate in a rectangle or square shape to supply a power source voltage to the integrated circuit, a main relay pad connected to one corner of the rectangular or square power source line, and at least one secondary relay pad connected to another respective corner of the rectangular or square power source line, and
wherein the support substrate has an external power source supply terminal and a relay line thereon to connect both the main relay pad and the at least one secondary relay pad to the external power source supply terminal.

2. The semiconductor package according to claim 1, wherein the at least one secondary relay pad includes a plurality of secondary relay pads, and the secondary relay pads are disposed at different corners of the rectangular or square power line.

3. The semiconductor package according to claim 1, wherein the relay line includes a wire bonding line.

4. The semiconductor package according to claim 2, wherein the main relay pad and the plurality of secondary relay pads are provided at predetermined intervals.

5. The semiconductor package according to claim 2, wherein each said secondary relay pad has its own relay line.

6. A semiconductor package comprising:
an IC chip including a generally polygonal substrate and an integrated circuit formed on the polygonal substrate; and
a support member to support the IC chip,
wherein the integrated circuit includes a power source line extending on the polygonal substrate to supply a power source voltage to the integrated circuit, a main relay pad provided in a first empty area on the polygonal substrate and connected to a first part of the power source line, and at least one secondary relay pad provided in a second empty area and connected to a second part of the power source line, and
wherein the support substrate has an external power source supply terminal, a first relay line to connect the main relay pad to the external power source supply terminal via the first relay line, and a second relay line to connect the at least one secondary relay pad to the external power source supply terminal via the second relay line.

7. The semiconductor package according to claim 6, wherein the at least one secondary relay pad includes a plurality of secondary relay pads provided at predetermined intervals.

8. The semiconductor package according to claim 6, wherein the first relay line includes a first wire bonding line and the second relay line includes a second wire bonding line.

9. The semiconductor package according to claim 7, wherein each said secondary relay pad has its own relay line.

10. The semiconductor package according to claim 7, wherein said first empty area is in the vicinity of a first corner of the polygonal substrate and said second empty area is in the vicinity of a second corner of the polygonal substrate.

11. The semiconductor package according to claim 7, wherein said at least one secondary relay pad provided in the second empty area includes two secondary relay pads provided in a single second empty area.

12. The semiconductor package according to claim 7, wherein said first part of the power source line is one angled part of the power source line and said second part of the power source line is another angled part of the power source line.
